(19) United States
(12) Patent Application Publication
(10) Pub. No.: US 2007/0034936 A1
(43) Pub. Date: Feb. 15, 2007

(54) Two-transistor memory cell and method for manufacturing

(75) Inventors: Robertus Theodorus Franciscus Van Schaijk, Leuven (BE); Michiel Slotboom, Leuven (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS N.V., Eindhoven (NL)

(21) Appl. No.: 10/574,030

(22) PCT Filed: Sep. 20, 2004
(86) PCT No.: PCT/IB04/51795

§ 371 Date: Mar. 27, 2006

(30) Foreign Application Priority Data
Sep. 30, 2003 (EP) 03103607.2

(51) Int. Cl. H01L 29/788

(52) U.S. Cl. 257/315

(57) ABSTRACT

The present invention provides a method of manufacturing on a substrate (50) a 2-transistor memory cell comprising a storage transistor (1) having a memory gate stack (1) and a selecting transistor, there being a tunnel dielectric layer (51) between the substrate (50) and the memory gate stack. (1). The method comprises forming the memory gate stack (1) by providing a first conductive layer (52) and a second conductive layer (54) and etching the second conductive layer (54) thus forming a control gate and etching the first conductive layer (52) thus forming a floating gate. The method is characterized in that it comprises, before etching the first conductive layer (52), forming spacers (81) against the control gate in the direction of a channel to be formed under the tunnel dielectric layer (51), and thereafter using the spacers (81) as a hard mask to etch the first conductive layer (52) thus forming the floating gate, thus making the floating gate self aligned with the control gate. The present invention also provides a memory cell wherein the control gate (54) is smaller than the floating gate (52), and spacers (81) are present next to the control gate (54).

The present invention relates to the field of non-volatile semiconductor memories and methods of operating the same. More particularly, this invention relates to a method of manufacturing a non-volatile memory cell, more particularly a 2-transistor memory cell, and to a memory cell thus obtained.

Non-volatile memories (NVMs) are used in a wide variety of commercial and military electronic devices and equipment, such as e.g. hand-held telephones, radios and digital cameras. The market for these electronic devices continues to demand devices with a lower voltage, lower power consumption and a decreased chip size.

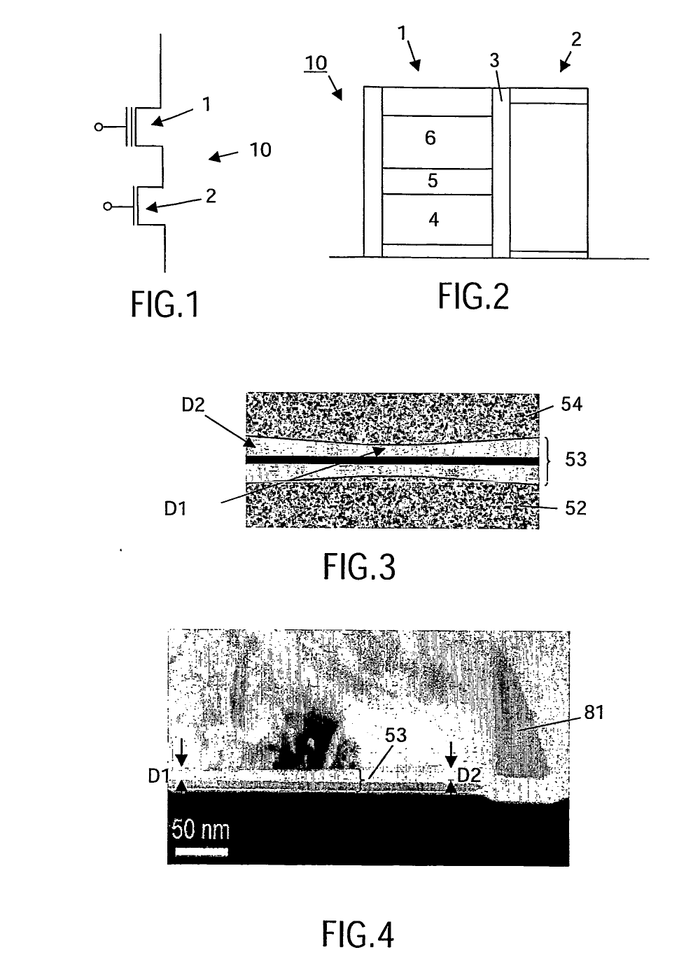

Flash memories or flash memory cells comprise a MOSFET with a floating gate between a control gate and a channel region. With the improvement of fabrication technologies, the floating gate size has been reduced to nanometer scale. These devices are basically miniature EEPROM cells in which electrons (or holes) are injected in a nanofloating gate by tunnel effect through an oxide barrier. Charges stored in the floating gate modify the device threshold voltage. Stacked gate technology is applied in the fabrication of modern non-volatile memory (NVM) cells with very high density. A schematic representation of a 2 transistor (2-T) flash EEPROM cell 10 is depicted in FIG. 1. A 2 transistor (2-T) flash EEPROM cell 10 comprises a storage transistor having a memory gate stack 1 and a selecting transistor having an access gate 2. A schematic cross-section through a compact 2-T flash EEPROM cell 10 is given in FIG. 2. In such memory cells 10, the access gate 2 and the memory gate stack 1 are isolated from each other by an isolation spacer 3. In a typical 2-T flash memory cell, this isolation is a TEOS (Tetraethyl Orthosilicate—Si(OC₂H₅)₄)—spacer. The gate stack 1 comprises a charge storing region 4 which can be for example a floating gate, an inter-poly dielectric 5 and a control gate 6.

U.S. Pat. No. 6,091,104 describes a method for manufacturing a compact 2-T flash EEPROM cell. A gate oxide is thermally grown on a silicon substrate. A layer of polysilicon (the poly-1 layer) is deposited on the oxide layer for use as a floating gate, and a dielectric film is formed on the poly-1 layer. A layer of polysilicon (the poly-2) layer is deposited on the dielectric film for use as a control gate. A layer of oxide or nitride, a capping layer, is then deposited on top of the poly-2 layer. During subsequent dry etching steps, the layer of oxide or nitride serves as a mask to prevent the poly-2 in the control gate area from being etched away.

A photolithographic mask is formed over the capping layer, and the unmasked portions of that capping layer and of the poly-2 layer are removed in an anisotropic dry etch, leaving only the portion of the poly-2 which forms the control gate. The photoresist is then stripped away, and an oxide layer is thermally grown on the side wall of the control gate polysilicon.

Using the control gate with the thermally grown oxide, and the capping layer on it as a mask, the interpoly dielectric layer and the poly-1 layer are etched in an anisotropic dry etch to form the interpoly dielectric and the floating gate.

Thereafter, in a thermal oxidation step, an access gate oxide is formed on the substrate, an oxide layer is formed on the exposed edge of the floating gate, and the oxide layer on the side wall of the control gate is made thicker.

It is a disadvantage of the above process that the silicon substrate is attacked during the anisotropic dry etch to form the interpoly dielectric and the floating gate. This introduces the need for a heavy cleaning step before the growth of the access gate oxide, introducing extra silicon recess. Also the oxide quality is worse than for oxides grown on a ‘fresh’ silicon surface. Furthermore the heavy cleaning also attacks the oxide formed on the side wall of the floating gate during the thermal oxidation step, which introduces extra process spread on this spacer thickness, resulting in a spread in drive characteristics.

Furthermore, the formation of the access gate oxide by thermal oxidation also results in a strong so-called ‘bird beak’ in the interpoly dielectric. This reduces the coupling between the floating gate and the control gate, and introduces extra spread on the threshold voltage for the devices, due to fluctuation in the ‘bird beak’.

Finally, the insulating layer between the access gate and the floating gate has the same thickness as the insulating layer between access gate and control gate, as both are manufactured at the same time. The thicker the insulating layer between the access gate and the control gate, the better, as a high voltage is present across this layer. However, the thicker the insulating layer between the access gate and the control gate, the more a read current is reduced, and the less efficient source side injection programming is.

It is an object of the present invention to provide a method of manufacturing a 2-transistor memory cell in which the insulating layer between the control gate and the access gate and the insulating layer between the floating gate and the access gate have different thicknesses, and to provide such 2-transistor memory cell.

The above objective is accomplished by a method and device according to the present invention.

The present invention provides a method of manufacturing on a substrate a 2-transistor memory cell comprising a storage transistor having a memory gate stack and a selecting transistor, there being a tunnel dielectric layer between the substrate and the memory gate stack. The method comprises forming the memory gate stack by providing a first conductive layer and a second conductive layer and etching the second conductive layer thus forming a control gate and etching the first conductive layer thus forming a floating gate. The method is characterized in that it comprises, before etching the first conductive layer, forming spacers against the control gate in the direction of a channel to be formed under the tunnel dielectric layer, and thereafter using the spacers as a hard mask to etch the first conductive layer thus forming the floating gate, thus making the floating gate self aligned with the control gate. The spacers may be formed from a dielectric material which has an oxygen diffusion through the material which is an order of magnitude smaller than oxygen diffusion through oxide spacers. The dielectric material which has an oxygen diffusion through the material which is an order of magnitude smaller than oxygen diffusion through oxide spacers may be one or more of silicon nitride, silicon carbide or metal oxide. With metal oxide is meant: high-k materials such as Al₃O₂, or HfO₂. They need to be materials which can be anisotropically etched and which are not attacked by the etch during removal of the tunnel dielectric material. Oxygen diffusion through an oxide is dependent on whether wet (using H₂O) or dry (using O₂) oxidation is performed, on the stability concentration of H₂O or O₂ in the silicon oxide and on the temperature of the process being carried out.

A method according to the present invention may furthermore comprise, before forming the memory gate stack, applying the tunnel dielectric layer on the substrate, and after formation of the memory gate stack, removing the tunnel dielectric layer by a selective etching technique at least at a location where the selecting transistor is to be formed, the selective etching technique preferentially etching the tunnel dielectric layer compared to the substrate. The selection ratio between the tunnel dielectric layer and the substrate may for example be 4:1 or higher. Removing the tunnel dielectric layer may comprise performing a wet etch. The use of the selective etching technique has the advantage that later on, when forming the access gate of the selecting transistor, an access gate dielectric, e.g. access gate oxide, can be grown with a higher quality than in prior art methods where access gate oxide has to be grown on attacked or deteriorated substrate.

After etching of the first conductive layer, a floating gate dielectric may be provided next to the formed floating gate. This means that floating gate dielectric and control gate dielectric are processed separately, and thus that they can have different thicknesses. Therefore, a thick isolation can be provided between the access gate and the control gate, where the high voltage is across, while a much thinner isolation may be formed between the access gate and the floating gate. This isolation between the access gate and the floating gate is also much thinner than in case of the prior art way of processing a compact 2-transistor cell. This thinner isolation results in increased read current, and also the source side injection programming efficiency is higher than in prior art devices.

The floating gate dielectric may be provided at the same time as providing an access gate dielectric.

When the memory gate stack comprises an interlayer dielectric layer between the first conductive layer and the second conductive layer, the method may furthermore comprise removing part of the interlayer dielectric layer after forming the control gate but before forming the spacers. Alternatively, the interlayer dielectric layer may be partly removed after forming the spacers. With this latter solution, the bird beak problem occurs to a lesser extent than in the prior art, and other advantages of the present invention are obtained.

The selecting transistor may comprise an access gate, and the method may comprise forming the access gate while the spacer at the access gate side is still present. This provides a better isolation between the control gate and the access gate. Alternatively, the spacers, or at least the spacer at the access gate side may be removed before implementing the access gate.

The present invention also provides a 2-transistor memory cell comprising a storage transistor and a selecting transistor, the storage transistor comprising a floating gate and a control gate, wherein the control gate is smaller than the floating gate, and spacers are present next to the control gate. The spacers may be made from a dielectric material which has an oxygen diffusion through the material which is an order of magnitude smaller than oxygen diffusion through oxide spacers. The dielectric material which has an oxygen diffusion through the material which is an order of magnitude smaller than oxygen diffusion through oxide spacers may be one or more of silicon nitride, silicon carbide or metal oxide.

When the selecting transistor comprises an access gate, the spacer being present between the control gate and the access gate and a floating gate dielectric being present between the floating gate and the access gate, the spacer may be thicker than the floating gate dielectric.

Preferably, in any of the devices according to the present invention, a surface of the substrate at locations next to the floating gate where no tunnel dielectric layer is present does not have etching erosion.

The present invention also provides an electronic device comprising a memory cell according to any of the embodiments of the present invention.

These and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

FIG. 1 is a schematic representation of a 2-transistor memory cell.

FIG. 2 is a vertical cross-section of a prior art 2-transistor memory cell.

FIG. 3 is an enlarged view of part of a first and second polysilicon layer with an ONO layer in between, with occurrence of the ‘bird beak’ phenomenon.

FIG. 4 is a TEM illustrating occurrence of the ‘bird beak’.

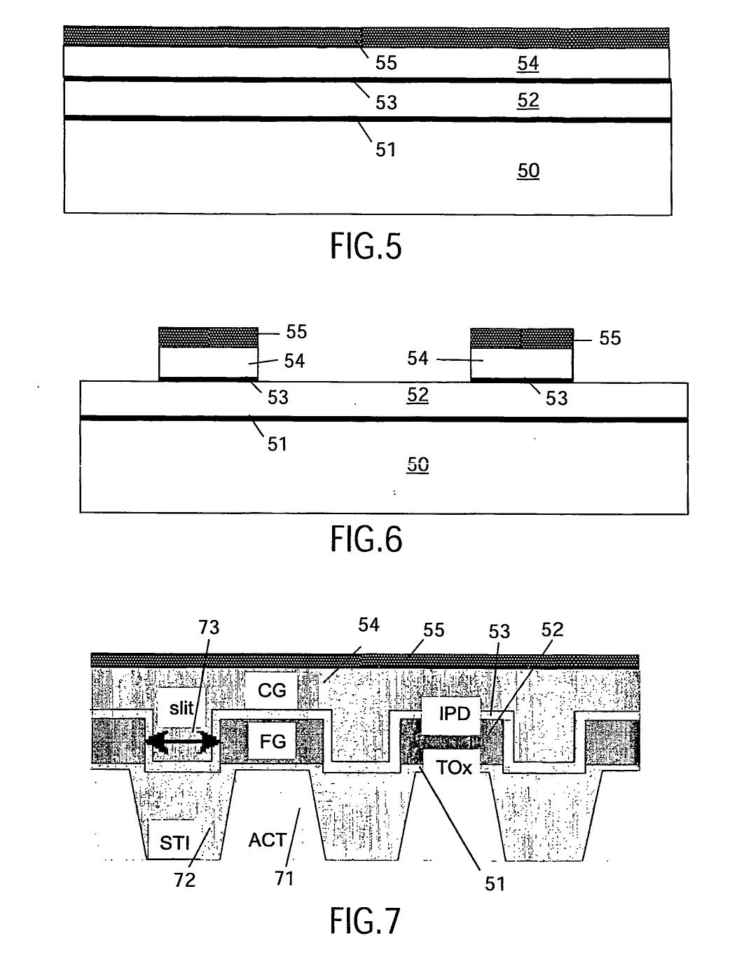

FIGS. 5 to 10 show different steps in the fabrication of a 2-T flash EEPROM cell according to an embodiment of the present invention.

FIG. 7 is a vertical cross-section of a 2-transistor memory cell, the cross-section being taken in a direction perpendicular to the cross-section of FIGS. 6-10.

In the different figures, the same reference figures refer to the same or analogous elements.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

According to the present invention, in a first step, a substrate 50 or a well in a substrate is provided. In embodiments of the present invention, the term “substrate” may include any underlying material or materials that may be used, or upon which a device, a circuit or an epitaxial layer may be formed. In other alternative embodiments, this “substrate” may include a semiconductor substrate such as e.g. a doped silicon, a gallium arsenide (GaAs), a gallium arsenide phosphide (GaAsP), a germanium (Ge), or a silicon germanium (SiGe) substrate. The “substrate” may include, for example, an insulating layer such as a SiO₂ or an Si₃N₄ layer in addition to a semiconductor substrate portion. Thus, the term substrate also includes silicon-on-glass, silicon-on sapphire substrates. The term “substrate” is thus used to define generally the elements for layers that underlie a layer or portions of interest. Also, the “substrate” may be any other base on which a layer is formed, for example a glass or metal layer. In the following processing will mainly be described with reference to silicon processing but the skilled person will appreciate that the present invention may be implemented based on other semiconductor material systems and that the skilled person can select suitable materials as equivalents of the dielectric and conductive materials described below.

Active areas 71 are defined by means of isolation layer such as a field oxide 72, e.g. made by a shallow trench insulation (STI) process. This defines the width of the transistors, as represented in FIG. 7. FIG. 7 is a cross-section in a direction perpendicular to the cross-section of FIG. 6, but in a later stage.

As shown in FIG. 5, on top of the substrate 50, a tunnel insulating material, for example a tunnel oxide (Tox) layer 51, e.g. comprising silicon dioxide, is formed, e.g. by thermally growing it in an oxygen-steam ambient, at a temperature between about 600 to 1000° C., to a thickness between about 6 to 15 nm. Alternatively for example a dry oxidation can be used for growing the tunnel oxide layer 51.

On top of the tunnel oxide layer 51, a first conductive layer, such as a first polysilicon layer 52 is deposited, which will later on form the floating gate (FG). The deposition of the first polysilicon layer 52 is preferably done by a CVD procedure, to a thickness between about 50 to 400 nm. Doping of the polysilicon layer 52 is either accomplished in situ, during deposition, e.g. via the addition of arsine or phosphine to a silane ambient, or via an ion implantation procedure, using for example arsenic (As) or phosphorous (P) ions applied to an intrinsically polysilicon layer. The polysilicon layer 52 is preferably highly doped, which means with a dopant concentration of at least 6.10¹⁹ cm³, preferably 3.10²⁰ cm³ or more, still more preferred 10²¹ cm³ or more. This doped first polysilicon layer 54 will later form a floating gate (FG).

The first polysilicon layer 52 is patterned with floating gate isolation means, e.g. slits 73, as illustrated in FIG. 7 using, for instance, conventional lithographic and photoresist techniques. These slits serve to isolate adjacent floating gates from each other, for example the floating gates are located on a same wordline but on different bitlines.

An interlayer dielectric or interpoly dielectric (IPD) 53 is formed over the first polysilicon layer 52, after the slits 73 are made. This IPD 53 comprises a dielectric material such as for example silicon oxide, and may be deposited via any suitable method such as an LPCVD or a PECVD procedure, to an equivalent oxide thickness (EOT) between about 10 to 30 nm. The IPD 53 preferably comprises other insulating materials, e.g. an Oxide Nitride Oxide (ONO) layer, and may be formed or grown by conventional techniques. An ONO layer comprises successive layers of silicon dioxide, silicon nitride and silicon dioxide. It is to be appreciated that the thickness of the IPD 53 in the drawings is shown to be relatively the same as the other layers for the ease of understanding; however, the IPD 53 is actually very thin relative to the first polysilicon layer 52 and a second polysilicon layer 54.

After forming the IPD layer 53, a second conductive layer, such as a second polysilicon layer 54, is deposited. The deposition of the second polysilicon layer 54 may be done by LPCVD procedures, to a thickness between about 50 to 400 nm. Doping of the second polysilicon layer 54 is either accomplished in situ, during deposition, via the addition of a suitable dopant impurity such as arsine or phosphine to a silane ambient, or via an ion implantation procedure, using such a dopant, e.g. arsenic or phosphorous ions applied to an intrinsically polysilicon layer. Again, the second polysilicon layer 54 is highly doped. This doped second polysilicon layer 54 will later form a control gate (CG).

An insulating layer or cap layer 55 is formed on top of the second polysilicon layer 54. This cap layer 55 may be formed of an insulating material such as oxide or nitride for example.

A resist or control gate mask (not represented in the drawings) is lithographically patterned over portions of the cap layer 55. This control gate mask is used to etch away, by means of an anisotropic etch, the cap layer 55, of the second polysilicon layer 54 and of the interpoly dielectric 53 which are not covered by the resist. The interpoly dielectric 53 can be selectively etched away with respect to the first polysilicon layer 52. The result so far is shown in FIG. 6.

After this etch, a layer which has as feature an absence of oxygen diffusion through its material is deposited. This layer may for example be a nitride layer; oxide based material is not suitable for being used. This layer is etched anisotropically, thus forming non-oxygen diffusing spacers 81 next to the remainder of the CG polysilicon layer 54, forming the CG, and next to the remainder of the IPD 53. The spacers 81 are control gate-access gate isolation means. The thickness of the spacer 81 is related to the thickness of the deposited layer, and should be sufficient to isolate the control gate from a later formed access gate.

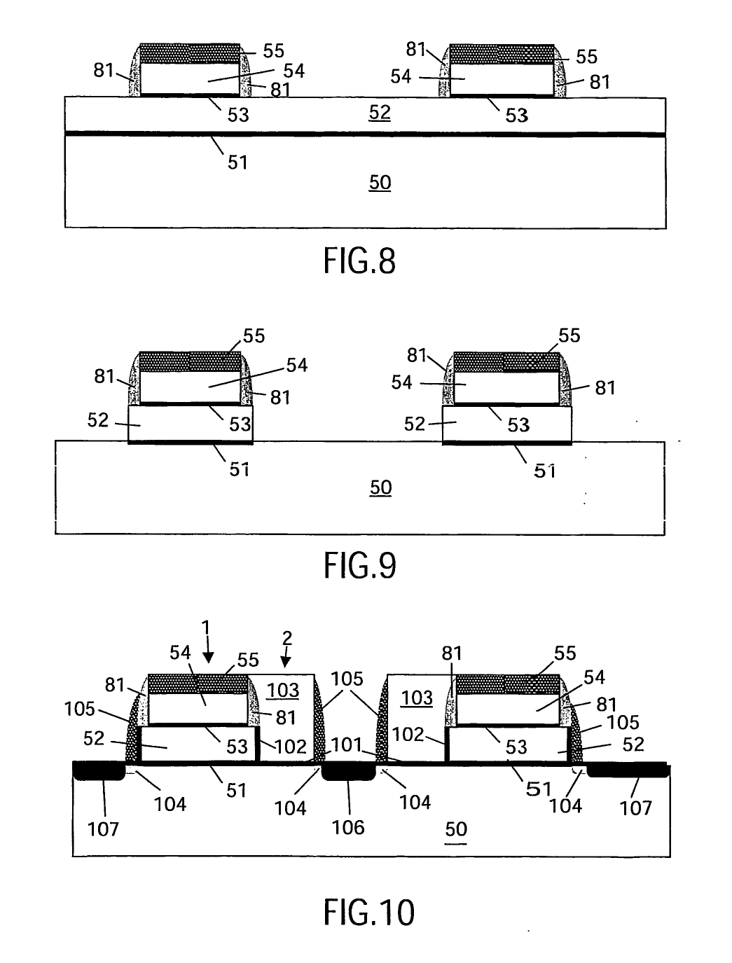

It is an advantage of the embodiment of the present invention represented in the drawings, and in particular in FIG. 8, that a so called ‘bird beak’ problem does not occur. During access gate oxidation later on, when forming access gate oxide 101 as explained later on with reference to FIG. 10, the already existing oxide, in contact with polysilicon, tends to grow from an original thickness DI to an increased thickness D2. Therefore, the form of the oxide of the IPD 53 becomes triangular and resembles a bird beak. The effect is schematically shown in FIG. 3. In FIG. 4, a TEM picture of the ‘bird beak’ phenomenon is illustrated.

The ‘bird beak’ effect is much more pronounced for deposited oxides compared with thermally grown oxides. This means that the effect is important for the interpoly dielectric 53. If the interpoly dielectric layer 53 is partly thicker than designed, the coupling of the FG with the CG is reduced. This increases the needed program and erase voltages, thus reducing applicability of these memory devices in low-power applications.

Furthermore, the ‘bird beak effect’ will not be uniform and depends on polysilicon grain sizes, grain orientation and doping distribution. This introduces extra spread in coupling, which directly translates in spread in the threshold voltage Vₜ of the memory devices. In a memory, one wants a small spread around the average threshold voltage Vₜ.

The above reduction in CG to FG coupling due to the ‘bird beak’ and the induced threshold voltage spread is reduced or will not be present in the proposed processing according to the present invention. Important in this processing is the fact that the spacers are not made of deposited oxide, but from a material with minimal oxygen diffusion, like nitride for example. With minimal oxygen diffusion is meant that too little oxygen is present to obtain a significant oxidation of silicon. This means that diffusion of oxygen through the spacers from material with minimal oxygen diffusion must be an order of magnitude smaller than diffusion of oxygen through oxide spacers. In a standard cell, where a spacer goes over the complete height of the storage transistor stack, the spacer cannot be made of nitride, because the nitride will be located close to the channel. Because nitride tends to trap electrons, this will influence the channel conduction.

In a next step, the remainder of the cap layer 55 and the spacers 81 are used as a hard mask for the etching of the floating gate layer 52. In the not shown embodiment mentioned hereinabove, the IPD 53 is also etched during this step. This etch should be an anisotropic etch which is selective towards the tunnel oxide layer 51, so that it stops on the tunnel oxide layer 51. Not etching the tunnel oxide at this moment prevents the substrate 50 from being attacked and thus deteriorated.

Next the non-covered parts of the tunnel oxide layer 51 can be removed by a wet etch, which does not attack the silicon substrate 50, the spacers 81 and the remainder of the cap layer 55. The result is as shown in FIG. 9.

In a next step, an access gate oxide 101 is provided. This may be done by growing it, for example by an oxidation step. The oxidation step preferably is a wet oxidation. By having chosen a high doping level in the first polysilicon layer 52, the oxide 102 on the side walls of the floating gate 52 grows faster than on the silicon substrate 50, due to high doping differences. The obtained thicker oxide 102 on the floating gate assures data retention. Alternatively, the access gate oxide can be deposited, or the access gate oxide can be applied by a combination of growing and depositing oxide.

It is an advantage of the present invention that the access gate oxide 101 is provided on top of a portion of non-attacked substrate material, which results in a better quality access gate oxide. Also the severe cleaning after spacer etching, and the related spread in spacer thickness can be prevented.

A next step is the deposition of access gate polysilicon 103, preferably in-situ doped. This access gate polysilicon 103 is preferably planarized, e.g. with poly-CMP (chemical mechanical polishing), after which the access gate is patterned in a conventional way.

Furthermore, as can also be seen from FIG. 10, it is an advantage of the processing according to the present invention that there is formed a thick isolation between the access gate and the control gate, across which there is a high gate voltage, and a much thinner isolation between the access gate and the floating gate. In the proposed processing, the stack etch is in two parts, and the isolation can be processed separately. This isolation between access gate and floating gate is furthermore much thinner than in conventional processing of a compact 2-transistor cell. This thinner isolation results in increased read current and also the source side injection programming efficiency is higher.

After forming of the access gate, a lightly doped drain (LDD) or medium doped drain (MDD) implant 104 may be carried out, i.e. an impurity implantation in the substrate 50 with a dose of the order of 10¹³-10¹⁴ atoms per cm². The purpose of this LDD or MDD implant 104 is to create a reduced doping gradient between a drain/source to be formed and a channel under the tunnel oxide 51, which lowers the maximum electric field in the channel in the vicinity of the drain/source.

Subsequently, offset spacers 105 for a highly doped drain (HDD) implant are provided for example from oxide, nitride or a combination of both. These are used to offset the HDD implant, thus forming source and drain regions 106, 107, as shown in FIG. 10. A highly doped implant preferably has an impurity concentration of the order of 10¹⁵ atoms per cm². The memory gate stack 1 does not overlap with the heavily doped source and drain regions 106, 107. As said previously, the LDD structure 104 ensures a low dopant gradient in the drain channel region, which reduces the maximum electric field in the drain—channel and source—channel interfaces.

Finally, the uncovered silicon and polysilicon areas are provided with a conductive layer, for example they may be silicidized. After the above steps, standard back-end processing can be applied to finish the memory.

It is to be understood that although preferred embodiments, specific constructions and configurations, as well as materials, have been discussed herein for devices according to the present invention, various changes or modifications in form and detail may be made without departing from the scope and spirit of this invention. For example, according to an alternative embodiment, not represented in the drawings, the anisotropic etch is used to etch away parts of the cap layer 55 and parts of the second polysilicon layer 54 which are not covered by the resist, the interpoly dielectric 53 being left intact. After this etch, non-oxygen diffusing spacers are formed next to the CG. If this embodiment is carried out, the ‘bird beak’ problem remains in a lesser extent, but the other advantages are kept: a wet etch can be carried out so that the substrate is not attacked and thus a better quality access gate oxide can be formed, there is less Vₜ spread, and the isolation between the access gate and the floating gate is much thinner than the isolation between the access gate and the control gate.

1. A method of manufacturing on a substrate a 2-transistor memory cell comprising a storage transistor having a memory gate stack and a selecting transistor, there being a tunnel dielectric layer between the substrate and the memory gate stack, the method comprising:
forming the memory gate stack by providing a first conductive layer and a second conductive layer and etching the second conductive layer thus forming a control gate and etching the first conductive layer thus forming a floating gate,
the method furthermore comprising, before etching the first conductive layer, forming spacers against the control gate in the direction of a channel to be formed under the tunnel dielectric layer, and thereafter using the spacers as a hard mask to etch the first conductive layer thus forming the floating gate.

2. A method according to claim 1, wherein the spacers are formed from a dielectric material having an oxygen diffusion through the material that is an order of magnitude smaller than oxygen diffusion through oxide spacers.

3. A method according to claim 2, wherein the dielectric material having an oxygen diffusion through the material that is an order of magnitude smaller than oxygen diffusion through oxide spacers includes one or more of silicon nitride, silicon carbide or metal oxide.

4. A method according to claim 1, furthermore comprising,
before forming the memory gate stack, applying the tunnel dielectric layer on the substrate, and
after formation of the memory gate stack, removing the tunnel dielectric layer by a selective etching technique at least at a location where the selecting transistor is to be formed, the selective etching technique preferentially etching the tunnel dielectric layer compared to the substrate.

5. A method according to claim 1, comprising,
after etching of the first conductive layer, providing a floating gate dielectric next to the formed floating gate and at the same time providing an access gate dielectric.

6. A method according to claim 1, the memory gate stack comprising an interlayer dielectric layer between the first conductive layer and the second conductive layer, the method furthermore comprising
removing part of the interlayer dielectric layer after forming the control gate but before forming the spacers.

7. A method according to claim 1, the selecting transistor comprising an access gate, the method comprising
forming the access gate while the spacer at the access gate side is still present.

8. A 2-transistor memory cell comprising,
a storage transistor and
a selecting transistor, the storage transistor comprising a floating gate and a control gate, wherein the control gate is smaller than the floating gate, and spacers are present next to the control gate.

9. A memory cell according to claim 8, wherein the spacers are made from a dielectric material having an oxygen diffusion through the material that is an order of magnitude smaller than oxygen diffusion through oxide spacers.

10. A memory cell according to claim 8, the selecting transistor comprising an access gate, a spacer being present between the control gate and the access gate and a floating gate dielectric being present between the floating gate and the access gate, wherein the spacer is thicker than the floating gate dielectric.

11. An electronic device comprising a 2-transistor memory cell, the 2-transistor memory cell including,
a storage transistor and
a selecting transistor, the storage transistor comprising a floating gate and a control gate, wherein the control gate is smaller than the floating gate, and spacers are present next to the control gate.

12. The electronic device as recited in claim 11, wherein the spacers are made from a dielectric material having an oxygen diffusion through the material that is an order of magnitude smaller than the oxygen diffusion through the oxide spacers.

13. The electronic device as recited in claim 12, wherein the selecting transistor includes,
an access gate,
a spacer being present between the control gate, and
the access gate and a floating gate dielectric being present between the floating gate and the access gate, wherein the spacer is thicker than the floating gate dielectric.
